(19) United States
(12) Patent Application Publication
(10) Pub. No.: US 2025/0112437 A1
(43) Pub. Date: Apr. 3, 2025

(54) BANDWIDTH IMPROVEMENT OF THROUGH-HOLE DISTRIBUTED FEEDBACK LASER

(71) Applicant: Keysight Technologies, Inc., Santa Rosa, CA (US)

(72) Inventor: Michael Thomas McTigue, Colorado Springs, CO (US)

(21) Appl. No.: 18/374,995

(22) Filed: Sep. 29, 2023

(51) Int. Cl. H01S 5/02212; H01S 5/12

(52) U.S. Cl. CPC H01S 5/02212; H01S 5/12

(57) ABSTRACT

A laser emitting device includes a casing and first, second and third through-hole leads protruding through the casing. A proximal end portion of each of the first through third through-hole leads is located within the casing, and a distal end portion of each of the first through third through-hole leads is located external the casing. The laser emitting device further includes a laser diode and a photodiode located within the casing. The laser diode includes a cathode electrically connected to the proximal end portion of the first through-hole lead and an anode electrically connected to the proximal end portion of the second through-hole lead, and the photodiode includes a cathode electrically connected to the anode of the laser diode and an anode electrically connected to the proximal end portion of the third through-hole lead. The laser emitting device still further includes a resistor mounted to an outside of the casing, and electrically connected between the casing and the distal end of the third through-hole lead.

### BACKGROUND

The inventive concepts generally relate to through-hole distributed feedback (DFB) lasers, and more particular, to techniques for improving the bandwidth of through-hole DFB laser.

DFB lasers typically include a light-emitting laser diode (LD) and a monitoring photodiode (PD) diode. These components may be mounted in a through-hole package having leads (or pins) that extend through one side of a circuit board and are soldered onto pads on the other side of the board. The leads are typically relatively long, and as a result, a loss of bandwidth can occur mostly due to parasitic inductances. In the case, for example, where an input of the DFB laser is coupled to an oscilloscope probe used in testing or analyzing a device under test (DUT), inductance can cause the laser diode (LD) current to fall off thereby limiting the bandwidth of the measurement.

Historically, the way to increase bandwidth of a through-hole laser (or other electronic components) is to mount the laser in such a way as to limit the length of the through-hole leads to the extent practicable. This can improve the bandwidth to a point, but further improvements bandwidths remain desirable.

### SUMMARY

According to an aspect of the inventive concepts, a laser emitting device is provided that includes a casing and first, second and third through-hole leads protruding through the casing. A proximal end portion of each of the first through third through-hole leads is located within the casing, and a distal end portion of each of the first through third through-hole leads is located external the casing. The laser emitting device further includes a laser diode and a photodiode located within the casing. The laser diode includes a cathode electrically connected to the proximal end portion of the first through-hole lead and an anode electrically connected to the proximal end portion of the second through-hole lead, and the photodiode includes a cathode electrically connected to the anode of the laser diode and an anode electrically connected to the proximal end portion of the third through-hole lead. The laser emitting device still further includes a resistor mounted to an outside of the casing, and electrically connected between the casing and the distal end of the third through-hole lead.

The laser diode may be a distributed feedback laser diode.

A length of the third through-hole lead external the casing may be less than a length of each of the first and second through-hole leads external the casing.

The distal end portion of the third through-hole lead may terminate at the connection with the resistor.

Respective leads of the resistor may be soldered to the distal end of the third through-hole lead and to the casing.

The anode of the photodiode may be wire-bonded to the proximal end portion of the third through-hole lead, the cathode of the photodiode is wire-bonded to the anode of the laser diode, the cathode of the laser diode may be wire-bonded to the proximal end portion of the first through-hole lead, and the anode of the laser diode may be wire-bonded to the proximal end portion of the second through-hole lead.

The laser emitting device may further include a fourth through-hole lead protruding through the casing and electrically connected to the casing. The fourth through-hole lead may be a ground lead.

According to another aspect of the inventive concepts, a probe assembly is provided which includes the laser emitting device described above, a direct current (DC) bias source electrically connected to the distal end of the second through-hole lead, and a probe assembly electrically connected to the distal end of the first through-hole lead.

The probe assembly may include a probe tip, an amplifier having an input electrically connected to an output of the probe tip, and a resistor electrically connected between an output of the amplifier and the distal end portion of the first through-hole lead. The casing may be grounded.

According to another aspect of the inventive concepts, a method of improving the bandwidth of a through-hole laser emitting device is provided. The through-hole laser emitting device includes a laser diode and a monitoring photodiode within a casing, and a plurality of through-hole leads extending through the casing. The method includes severing, external the casing, a one of the through-hole leads that is connected to an anode of the monitoring photodiode, wherein a severed end of the one of the through-hole leads is in close proximity an outer surface of the casing, and mounting a resistor to an outside of the casing such that the resistor is electrically connected between the casing and the severed end of the one of the through-hole leads.

The laser diode may a distributed feedback (DFB) laser diode. The method may further include reverse biasing the monitoring photo diode during operation of the DFB laser.

According to another aspect of the inventive concepts, a method of improving the bandwidth of a through-hole laser emitting device is provided. The through-hole laser emitting device includes a laser diode and a monitoring photodiode within a casing, and a plurality of through-hole leads extending through the casing. The method includes mounting a resistor to an outside of the casing such that the resistor is electrically connected between the casing and a one of the through-hole leads that is connected to an anode of the monitoring photodiode, and severing, external the casing, the one of the through-hole leads that is connected to the anode of the monitoring photodiode, wherein a severed end of the one of the through-hole leads is in close proximity an outer surface of the casing.

The laser diode may a distributed feedback (DFB) laser diode. The method may further include reverse biasing the monitoring photo diode during operation of the DFB laser.

### BRIEF DESCRIPTION OF THE DRAWINGS

The above and other aspects and features of the inventive concepts will become readily apparent from the detailed description that follows, with reference to the accompanying drawings, in which:

FIG. 1A is an exemplary perspective view from the top and side of a distributed feedback (DFB) laser, and FIG. 1B is a perspective view from the bottom of the DFB laser;

FIG. 2A is an exemplary schematic cross-sectional view of the DFB laser of FIG. 1A;

FIG. 2B is an exemplary equivalent circuit diagram of the DFB laser of FIG. 1A;

FIG. 3 is an exemplary schematic cross-sectional view of a DFB laser according to an embodiment of the inventive concepts;

FIG. 4 illustrates an equivalent circuit diagram of a through-hold DFB laser connected to a probe assembly according to an embodiment of the inventive concepts.

FIG. 5 is a simplified circuit diagram of the probe assembly of FIG. 4 operatively connected to an oscilloscope;

FIGS. 6 and 7 are flowcharts for reference in describing alternative methods of achieving an RLC circuit of the embodiments of the inventive concepts;

FIG. 8 is a diagram for reference in describing the effects of the embodiment described above;

FIG. 9A illustrates an example of the frequency response without an RLC network of the present embodiments; and

FIG. 9B illustrates an example of the frequency response with the RLC network of the present embodiments.

### DETAILED DESCRIPTION

In the following detailed description, for the purposes of explanation and not limitation, representative embodiments disclosing specific details are set forth in order to provide a thorough understanding of embodiments according to the present teachings. However, other embodiments consistent with the present disclosure that depart from specific details disclosed herein remain within the scope of the appended claims. Descriptions of known systems, devices, materials, methods of operation and methods of manufacture may be omitted so as to avoid obscuring the description of the representative embodiments. Nonetheless, systems, devices, materials and methods that are within the purview of one of ordinary skill in the art are within the scope of the present teachings and may be used in accordance with the representative embodiments. It is to be understood that the terminology used herein is for purposes of describing particular embodiments only and is not intended to be limiting. Definitions and explanations for terms herein are in addition to the technical and scientific meanings of the terms as commonly understood and accepted in the technical field of the present teachings.

It will be understood that, although the terms first, second, third etc. may be used herein to describe various elements or components, these elements or components should not be limited by these terms. These terms are only used to distinguish one element or component from another element or component. Thus, a first element or component discussed below could be termed a second element or component without departing from the teachings of the inventive concept.

As used in the specification and appended claims, the singular forms of terms ‘a’, ‘an’ and ‘the’ are intended to include both singular and plural forms, unless the context clearly dictates otherwise. Additionally, the terms “comprises”, and/or “comprising,” and/or similar terms when used in this specification, specify the presence of stated features, elements, and/or components, but do not preclude the presence or addition of one or more other features, elements, components, and/or groups thereof. As used herein, the term “and/or” includes any and all combinations of one or more of the associated listed items.

With respect to the drawings, it is emphasized that the illustrated features and elements are not necessarily drawn to scale. In fact, the dimensions may be arbitrarily increased or decreased for clarity of discussion. Wherever applicable and practical, like reference numerals refer to like elements.

The present disclosure, through one or more of its various aspects, embodiments and/or specific features or sub-components, is thus intended to bring out one or more of the advantages as specifically noted below.

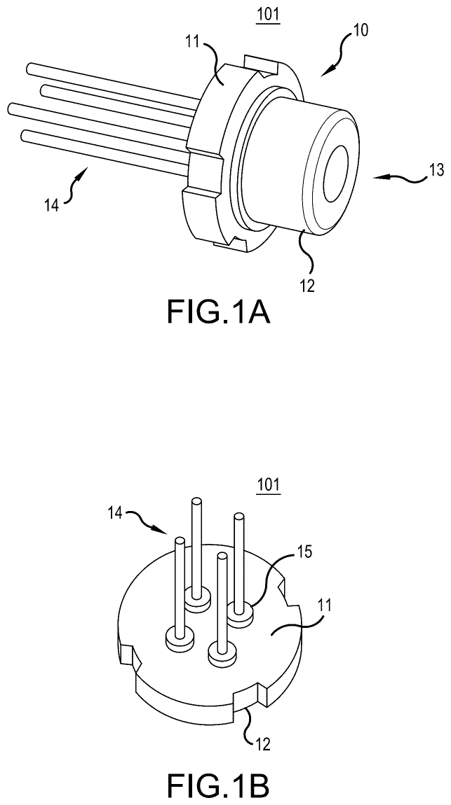

FIG. 1A is an exemplary perspective view from the top and side of a distributed feedback (DFB) laser 101, and FIG. 1B is a perspective view from the bottom of the DFB laser 101.

Referring to FIGS. 1A and 1B, the DFB laser 101 of this example includes a casing 10 having a base 11 and a cap 12 fixed to the top of the base 11. Each of the base 11 and cap 12 may be made of the same or different metals or metal alloys, such as copper or a copper alloy. As will be explained below, the casing 10 contains a photodiode and laser diode. The laser diode is positioned within the casing 10 to emit a laser beam through a window 13 located in the upper surface of the cap 12 or alternatively into a connected fiber. The photodiode is also positioned within the casing 10 and detects (monitors) an output power of the laser diode.

Also in the example of FIGS. 1A and 1B, the DFB laser 101 includes multiple through-hole leads 14 which protrude from through-holes 15 located in the base 11. For this reason, the DFB laser 101 may be referred to as a “through-hole DFB laser”. The illustrated example includes four (4) through-hole leads 14. However, depending on the internal circuitry of the DFB laser 101, more than four through-hole leads or less than four through-hole leads may be provided.

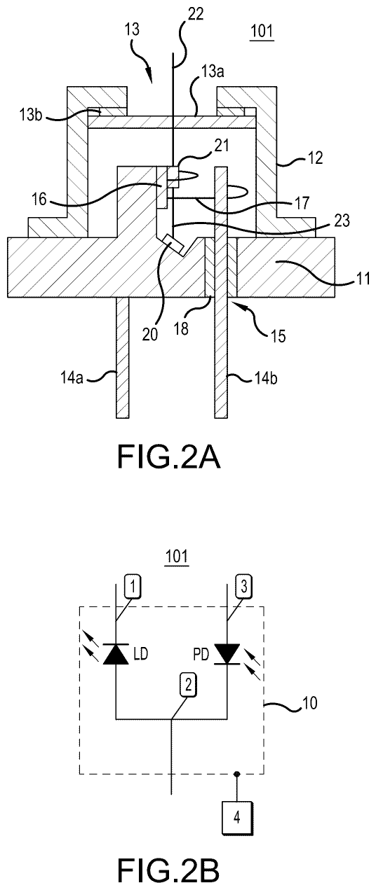

FIG. 2A is an exemplary schematic cross-sectional view of the DFB laser 101. As shown, the cap 12 is fixed to an upper surface of the base 11, and through-hole leads 14a and 14b protrude from the bottom surface of the base 11. Light emitted from the laser 101 can exit either by a window (e.g., the window 13) in the top of the through-hole package into free air or into a connected optical fiber for transport to a receiving optical-to-electrical module in the system. For convenience of the drawing, FIG. 2A only depicts two (2) through-hole leads 14a and 14b, but it will be understood that additional through-hole leads may be provided. FIG. 2A also depicts the through-hole lead 14b extending through a through-hole 15 in the base 11. In the illustrated example, the through-hole lead 14b is insulated from the base 11 by an insulating material 18. The insulating material 18 may, for example, be composed of glass. Any remaining through-hole leads of the DFB laser 101 may be similarly configured, except for a through-hole lead (if any) that functions to electrically ground the casing 10. Any such ground through-hole lead may be directly or indirectly electrically connected to the base 11.

Still referring to FIG. 2A, the bass 11 includes support surfaces within the casing 10 for supporting a photodiode 20 and laser diode 21. The laser diode 21 in particular may be mounted to a heat sink 16 that is fixed to the base 11 within the casing 10. In this particular example, the laser diode 21 is configured to emit laser light 22 from a light emitting surface thereof, and a monitoring light 23 from an opposite surface thereof. The monitoring light 23 is incident on the photodiode 20, which detects an output power of the laser diode 21. Also in this example, the laser diode 21, photodiode 20 and through-hole leads 14a and 14b are connected by bonding wires 17 to form a circuit such as that shown in FIG. 2B described next.

FIG. 2B is an exemplary equivalent circuit diagram of the DFB laser 101. In the figure, representative through-hole leads of the DFB laser 101 are labelled by the boxed numbers 1, 2, 3 and 4. As shown, a cathode of the laser diode LD is electrically connected to the first through-hole lead 1 and an anode of the laser diode LD is electrically connected to a second through-hole lead 2. Further, a cathode of the photodiode PD is electrically connected to the second through-hole lead 2 (i.e., to the anode of the laser diode LD), and an anode of the photodiode PD is electrically connected to a third through-hole lead 3. Also, the casing 10 may be electrically connected to a fourth through-hole lead 4.

In operation, a DC voltage bias may be applied the second through-hole lead 2, while an input signal (e.g., a radio frequency (RF) signal from a test probe) may be applied to the first through-hole lead 1. An output power of the laser diode LD will depend on the current flowing through the laser diode and a temperature of the laser diode. In the meantime, the photodiode PD receives a portion of the overall light emitted by the laser diode LD, and outputs a voltage correlating to the output power of the laser diode LD. In some examples, light emitted by the laser diode LD is fed to the optical input of an oscilloscope or similar analyzer device.

As explained above, the inside the through-hole package of a laser diode may include a photodiode that can be used to monitor the diode output. In some applications, however, the photodiode is not needed and is therefore not utilized for its intended purpose (i.e., monitoring). As will be explained below, in embodiments of the inventive concepts, the non-utilized photodiode may be used to implement a series RLC network that can improve the bandwidth of the laser diode, i.e., cause the current in the laser diode to not fall off as much over frequency. The inductance L of this network is the parasitic inductance of through-hole leads (pins) and wire bonds. The capacitance C is the capacitance of the reverse (i.e., off) photodiode. The resistance R is an external resistor (surface mount or other) connected to a through-hole lead from the photodiode to the case ground of the laser package. Inductance getting to this external resistor may be leveraged to tune the response.

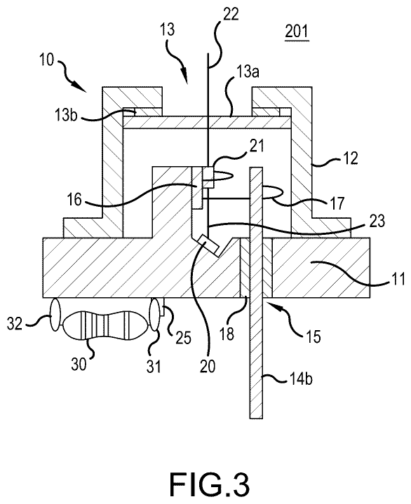

FIG. 3 is an exemplary schematic cross-sectional view of a DFB laser 201 according to an embodiment of the inventive concepts. In the example of this embodiment, the DFB laser 201 is a post-manufacture modified version of the DFB laser 101 described above in connection with FIGS. 1A to 2B. As such, like elements are identified by like reference numbers in the figures.

Referring to FIG. 3, a casing 10 includes a base 11 and a cap 12 fixed to the top of the base 11. Each of the base 11 and cap 12 may be made of the same or different metals or metal alloys, such as copper or a copper alloy. The casing 10 contains a photodiode 20 and laser diode 21. The laser diode 21 is positioned within the casing 10 to emit a laser beam through a window 13 located in the upper surface of the cap 12. In embodiments of the inventive concepts, the laser diode 21 is DFB laser diode.

The cap 12 is fixed to an upper surface of a base 11, and pins 25 and 14b protrude from the bottom surface of the base 11. For convenience of the drawing, FIG. 3 only depicts two (2) pins 25 and 14b, but it will be understood that additional pins may be provided. FIG. 3 also depicts the pin 14b extending through a through-hole 15 in the base 11. In the illustrated example, the pin 14b is insulated from the base 11 by an insulating material 18. The insulating material 18 may, for example, be composed of glass. Any remaining pins of the DFB laser 101 may be similarly configured, except for a pin (if any) that functions to electrically ground the casing 10. Any such ground pin may be directly or indirectly electrically connected to the base 11.

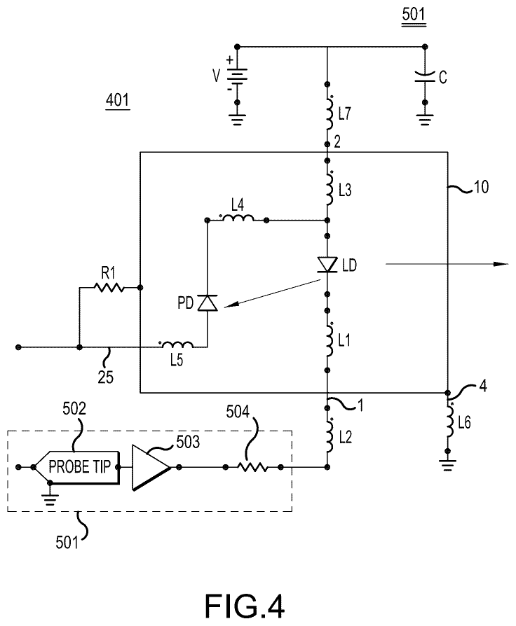

Still referring to FIG. 3, the bass 11 includes support surfaces within the casing 10 for supporting the photodiode 20 and the laser diode 21. The laser diode 21 in particular may be mounted to a heat sink 16 that is fixed to the base 11 within the casing 10. In this particular example, the laser diode 21 is configured to emit laser light 22 from a light emitting surface thereof, and a monitoring light 23 from an opposite surface thereof. The monitoring light 23 may be incident on the photodiode 20. Also in this example, the laser diode 21, photodiode 20 and through-hole leads 25 and 14b are connected by bonding wires 17 to form a circuit such as that shown in FIG. 4 described later herein. Of particular note, in this example, the through-hole lead 25 is connected to the anode of the photodiode 21.

The DFB laser 201 further includes a resistor 30 external the casing 10. In this example, the resistor 30 is mounted to the lower surface of the base 11 by solder 31 and 32. In particular, the solder 31 connects one terminal of the resistor 30 to the through-hole lead 25, and another terminal of the resistor 30 to the base 11. However, the inventive concepts are not limited to the manner in which the resistor 30 is mounted to the casing 10, so long as the end result is the resistor 30 being electrically connected between through-hole lead 25 (which is connected to the anode of the photodiode 20) and a reference voltage such as ground.

As represented in FIG. 3, the through-hole lead 25 is severed in close proximity to the base 11. As such, a length of the through-hole lead 25 external the casing is less than a length of each of the remaining through-hole leads external the casing.

In some embodiments of the inventive concepts, an input of the through-hole DFB laser is connected to the output of a probe assembly, such as that probe assembly of an oscilloscope or other test equipment. FIG. 4 illustrates an equivalent circuit diagram of a through-hold DFB laser 401 connected to a probe assembly 501 according to an embodiment of the inventive concepts.

Referring to FIG. 4, a photo diode PD and a laser diode LD are contained within a casing 10. In the figure, reference numerals 1, 2, 3 and 25 denote through-hole leads of the through-hold DFB laser 401, and L1 through L6 denote parasitic inductances of the through-hole leads an any bonding wires connected between the through-hole leads and the photo diode PD and the laser diode LD.

The through-hold lead 25 connected to the anode of the photo diode PD would normally include a parasitic inductance L8. However, as represented by the X over L8, this inductive component is removed by severing the lead 25 in close proximity to the outer surface of the casing 10 as described previously. As also described previously, a resistor R1 is connected between the severed lead 25 and the casing 10. The resistor R1 of FIG. 4 corresponds to the resistor 30 of FIG. 3.

A direct current (DC) bias source electrically connected to the distal end of the second through-hole lead 2. In the example of FIG. 4, the DC bias source includes a voltage source V and a filtering capacitor C. Here, the laser diode LD is forward biased, and as described previously, the photo diode PD is reversed biased.

The probe assembly 501 is connected to the input of the through-hole DFB layer 401. That is, as shown in FIG. 4, the probe assembly 501 is connected to the distal end of the through-hole lead 1 that is coupled to the anode of the laser diode LD. In the example of FIG. 4, the probe assembly includes a probe tip 502, an amplifier 503 having an input electrically connected to an output of the probe tip, and a resistor 504 electrically connected between an output of the amplifier 503 and the distal end portion of the first through-hole lead 1. However, the inventive concepts are not limited by the particularities of the probe assembly 501. In operation, the electrical signals picked up by the probe tip 502 are amplified and applied to the cathode of the laser diode LD, and the laser light emitted by the laser diode LD is modulated according to the thus applied electrical signals.

Also, in the example of the present embodiment, the casing 10 is grounded, thereby also grounding the resistor R1.

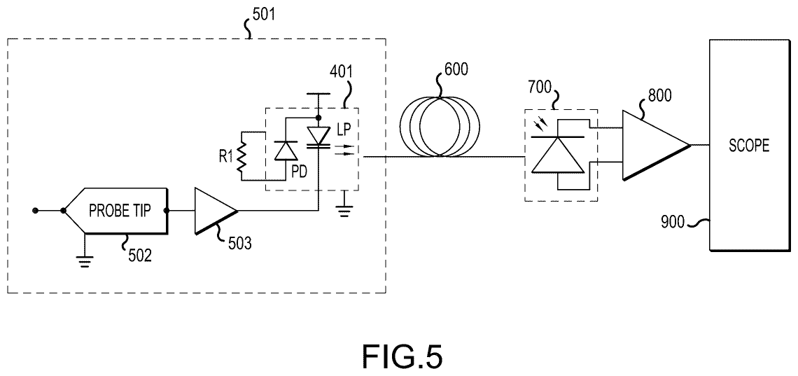

FIG. 5 is a simplified circuit diagram of the probe assembly 501 of FIG. 4 operatively connected to an oscilloscope 900. Like reference numbers refer to like elements, and an description of those elements already described in connection with FIG. 4 is not repeated below to avoid redundancy in the description.

As represented in FIG. 5, the laser light emitted by the laser diode LD is applied to one end of an optical carrier (e.g., optical cable) 600. The laser light propagates through the carrier 600 and is incident on a photo diode 700 which convert the laser light energy to an electrical signal. The electrical signal output by the photo diode 700 is amplified by an amplifier 800, and applied to the oscilloscope 900 where it is displayed and/or analyzed.

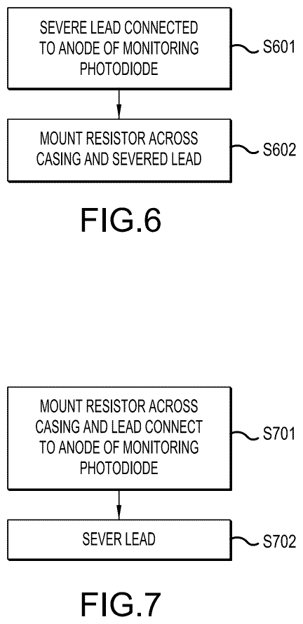

As described previously, in at least some embodiments of the inventive concepts, the through-hole lead coupled to the photo diode of the DFB laser is severed to substantially eliminate it parasitic inductance, and a resistive element coupled between the lead and casing (or ground) to add a resistive component that improves the bandwidth of DFB laser when the photo diode is reversed biased. FIGS. 6 and 7 are flowcharts for reference in describing alternative methods of achieving this modification.

Referring to FIG. 6, at S601, a one of the through-hole leads that is connected to an anode of the monitoring photodiode is severed outside the casing, where a severed end of the one of the through-hole leads is preferably in close proximity an outer surface of the casing.

Next, as S602, a resistor is mounted to an outside of the casing such that the resistor is electrically connected between the casing and the severed end of the one of the through-hole leads. Here, the resistor may be mounted by solder or other suitable means.

Alternatively, referring to FIG. 7, at S701, a resistor is mounted to an outside of the casing such that the resistor is electrically connected between the casing and a one of the through-hole leads that is connected to an anode of the monitoring photodiode. Again, the resistor may be mounted by solder or other suitable means.

Next, as S702, the one of the through-hole leads that is connected to the anode of the monitoring photodiode is severed outside the casing, wherein a severed end of the one of the through-hole leads is preferably in close proximity an outer surface of the casing.

Hereinabove, “close proximity” means the severed end of the through-hole lead is as close as practicably possible to the casing but still protrudes from the casing by an amount sufficient to practicably allow for soldering of the resistor to the through-hole lead (see in FIG. 6). Or, in the case where the resistor is soldered to the casing before the through-hole lead is severed (as in FIG. 7), the through-hole lead is severed as close a practicable to the solder without damaging to the solder.

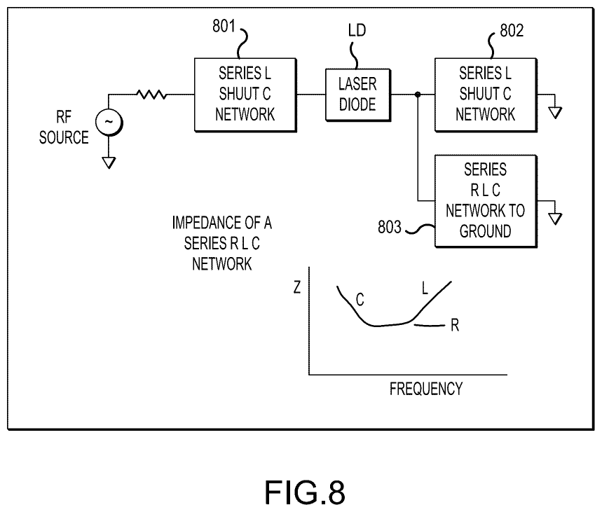

FIG. 8 is a diagram for reference in describing the effects of the embodiment described above. As described previously, in embodiments of the inventive concepts, the non-utilized photodiode may be used to implement a series RLC network that can improve the bandwidth of the laser diode, i.e., cause the current in the laser diode to not fall off as much over frequency. The inductance L of this network is the parasitic inductance of through-hole leads (pins) and wire bonds. The capacitance C is the capacitance of the reverse (i.e., off) photodiode. The resistance R is an external resistor (surface mount or other) connected to a through-hole lead from the photodiode to the case ground of the laser package. Inductance getting to this external resistor may be leveraged to tune the response.

Referring to FIG. 8, a first series L shunt C network is present at the input of the laser diode LD. The impedance looking into a second series L shunt C network 802 will increase with frequency. The second series L shunt C network 802 goes around and looks inductive over the bandwidth of interest. Without the series RLC network 803 this can cause the current in the laser diode LD to decrease with frequency and thus reduce the light output of the laser diode LD versus frequency. With the proper compensating input impedance of the series RLC network the current in the laser diode LD can be preserved to thereby extend the bandwidth of the output light. For a particular through hole laser diode the placement and value of the resistor terminating the series RLC network can be empirically determined.

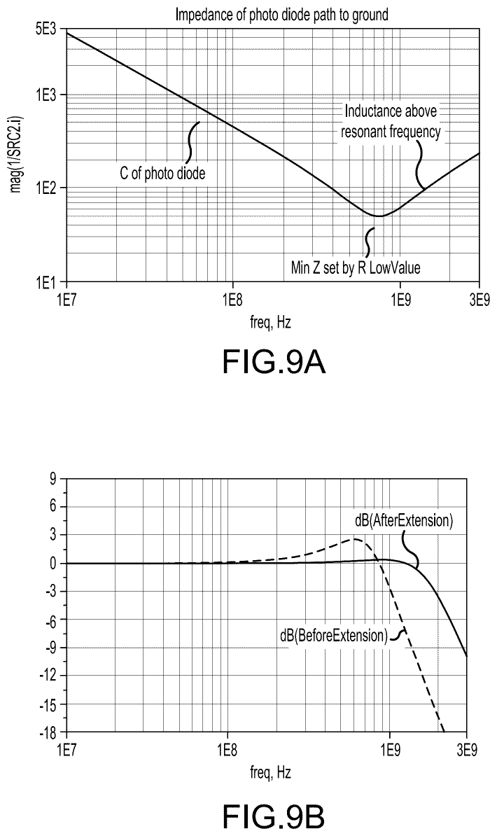

Attention is next directed to the graphs of FIGS. 9A and 9B.

FIG. 9A illustrates an example of the impedance of the photo diode LD to ground relative to frequency. As shown, the impedance drops primarily according to a capacitance C of the photo diode LD to a minimum Z, where Z is set by the resistance R of the resistor 30 (FIG. 3) as discussed above in connection with FIG. 8. Then, above the resonant frequency, the impedance gradually increases as shown.

FIG. 9B illustrates an example of the frequency response (in dB) to of a non-modified DFB laser diode package (the dashed line), and a DFB laser diode package that has been modified in accordance with the embodiments described herein (the solid line). As shown, peaking is reduced in the compensated response relative to the uncompensated response. Further, the inductance after the minimum Z (FIG. 9A) in the impedance is in parallel with the inductance of the second series L shunt C network described above in connection with FIG. 8. This reduces the net impedance L, and the frequency at which the current in the laser starts to roll off is pushed up which increases the obtained bandwidth.

The illustrations of the embodiments described herein are intended to provide a general understanding of the structure of the various embodiments. The illustrations are not intended to serve as a complete description of all of the elements and features of the disclosure described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and, as suggested earlier, may not be drawn to scale. Certain proportions within the illustrations may be exaggerated, while other proportions may be minimized. Accordingly, the disclosure and the figures are to be regarded as illustrative rather than restrictive.

One or more embodiments of the disclosure may be referred to herein, individually and/or collectively, by the term “invention” or “inventive concept” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

The Abstract of the Disclosure is provided to comply with 37 C.F.R. § 1.72 (b) and is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The preceding description of the disclosed embodiments is provided to enable any person skilled in the art to practice the concepts described in the present disclosure. As such, the above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents and shall not be restricted or limited by the foregoing detailed description.

What is claimed is:

1. A laser emitting device, comprising:
a casing:
first, second and third through-hole leads protruding through the casing, wherein a proximal end portion of each of the first through third through-hole leads is located within the casing, and a distal end portion of each of the first through third through-hole leads is located external the casing;
a laser diode located within the casing, the laser diode including a cathode electrically connected to the proximal end portion of the first through-hole lead and an anode electrically connected to the proximal end portion of the second through-hole lead;
a photodiode located within the casing, the photodiode including a cathode electrically connected to the anode of the laser diode and an anode electrically connected to the proximal end portion of the third through-hole lead; and
a resistor mounted to an outside of the casing, and electrically connected between the casing and the distal end of the third through-hole lead.

2. The laser emitting device of claim 1, wherein the laser diode is a distributed feedback laser diode.

3. The laser emitting device of claim 1, wherein a length of the third through-hole lead external the casing is less than a length of each of the first and second through-hole leads external the casing.

4. The laser emitting device of claim 1, wherein the distal end portion of the third through-hole lead terminates at the connection with the resistor.

5. The laser emitting device of claim 4, wherein respective leads of the resistor are soldered to the distal end of the third through-hole lead and to the casing.

6. The laser emitting device of claim 1, wherein the anode of the photodiode is wire-bonded to the proximal end portion of the third through-hole lead, the cathode of the photodiode is wire-bonded to the anode of the laser diode, the cathode of the laser diode is wire-bonded to the proximal end portion of the first through-hole lead, and the anode of the er diode is wire-bonded to the proximal end portion of the second through-hole lead.

7. The laser emitting device of claim 1, further comprising a fourth through-hole lead protruding through the casing and electrically connected to the casing.

8. The DFB laser of claim 7, wherein the fourth through-hole lead is a ground lead.

9. A probe assembly, comprising:
the laser emitting device of claim 1;
a direct current (DC) bias source electrically connected to the distal end of the second through-hole lead;
a probe assembly electrically connected to the distal end of the first through-hole lead.

10. The probe assembly of claim 9, wherein the probe assembly comprises:
a probe tip;
an amplifier having an input electrically connected to an output of the probe tip; and
a resistor electrically connected between an output of the amplifier and the distal end portion of the first through-hole lead.

11. The probe assembly of claim 10, wherein the casing is grounded.

12. A method of improving the bandwidth of a through-hole laser emitting device, the through-hole laser emitting device including a laser diode and a monitoring photodiode within a casing, and a plurality of through-hole leads extending through the casing, the method comprising:
severing, external the casing, a one of the through-hole leads that is connected to an anode of the monitoring photodiode, wherein a severed end of the one of the through-hole leads is in close proximity an outer surface of the casing; and
mounting a resistor to an outside of the casing such that the resistor is electrically connected between the casing and the severed end of the one of the through-hole leads.

13. The method of claim 12, wherein the laser diode is a distributed feedback (DFB) laser diode.

14. The method of claim 13, further comprising reverse biasing the monitoring photo diode during operation of the DFB laser.

15. A method of improving the bandwidth of a through-hole laser emitting device, the through-hole laser emitting device including a laser diode and a monitoring photodiode within a casing, and a plurality of through-hole leads extending through the casing, the method comprising:
mounting a resistor to an outside of the casing such that the resistor is electrically connected between the casing and a one of the through-hole leads that is connected to an anode of the monitoring photodiode; and
severing, external the casing, the one of the through-hole leads that is connected to the anode of the monitoring photodiode, wherein a severed end of the one of the through-hole leads is in close proximity an outer surface of the casing.

16. The method of claim 15, wherein the laser diode is a distributed feedback (DFB) laser diode.

17. The method of claim 16, further comprising reverse biasing the monitoring photo diode during operation of the DFB laser.
